(19) United States
(12) Patent Application Publication
(10) Pub. No.: US 2025/0233116 A1
(43) Pub. Date: Jul. 17, 2025

(54) Electronic Device and Manufacturing Method Thereof

(71) Applicant: Diodes Incorporated, Plano, TX (US)

(72) Inventors: Shu-Hao LIN, New Taipei City (TW); Ming-Wei TSAI, New Taipei City (TW); Chiao-Shun CHUANG, New Taipei City (TW)

(21) Appl. No.: 18/627,354

(22) Filed: Apr. 4, 2024

(30) Foreign Application Priority Data
Jan. 17, 2024 (CN) 202410067758.0

(51) Int. Cl. H01L 25/07; H01L 21/48; H01L 21/56; H01L 23/31; H01L 23/373; H01L 25/00

(52) U.S. Cl. CPC H01L 25/072; H01L 21/4807; H01L 21/565; H01L 23/3142; H01L 23/3735; H01L 25/50

(57) ABSTRACT

An electronic device includes a first semiconductor chip on a first substrate and a second semiconductor chip on a second substrate separated from the first substrate, with both semiconductor chips arranged between the first substrate and the second substrate. The first semiconductor chip includes a drain coupled to the first substrate and located on a side of the first semiconductor chip, with a gate and a source located on an opposite side of the first semiconductor chip. The second semiconductor chip has a drain coupled to the second substrate and located on a side of the second semiconductor chip, with a gate and a source located on an opposite side of the second semiconductor chip. A first connection structure couples the source of the first semiconductor chip to the second substrate. A second connection structure couples the source of the second semiconductor chip to the first substrate.

### CROSS-REFERENCE TO RELATED APPLICATIONS

This patent application claims priority to Chinese Patent Application No. 202410067758.0, filed on Jan. 17, 2024 and entitled “Electronic device and manufacturing method thereof,” which is hereby incorporated by reference herein as if reproduced in its entirety.

### TECHNICAL FIELD

The present disclosure relates generally to the field of electronic devices and components, and in particular embodiments, to techniques and mechanisms for an electronic device and a manufacturing method thereof. In some embodiments, an electronic device having a double-layer substrate and a heat dissipation structure is provided.

### BACKGROUND

An electronic device (or unit, module, component) may include multiple chips or integrated circuits (ICs). With the trend of miniaturization, the circuit wiring area on a printed circuit board (PCB) is reduced. At the same time, in order to meet the requirements of higher current and power, the total number of chips, the number of input/output (I/O) connection pins/leads and the interconnection paths in electronic devices will be increased, and the structures will become more complex. How to reduce resistance, disperse heat sources and improve heat dissipation efficiency will become more important.

### SUMMARY

Technical advantages are generally achieved, by embodiments of this disclosure which describe an electronic device and a manufacturing method thereof.

Embodiments of the present disclosure relate to an electronic device. The electronic device includes: a first substrate; a first semiconductor chip having a first gate, a first source and a first drain, wherein the first drain is located on one side of the first semiconductor chip, the first gate and the first source are located on an opposite side of the first semiconductor chip, and the first drain is coupled to the first substrate; a second substrate physically separated from the first substrate; a second semiconductor chip having a second gate, a second source and a second drain, wherein the second drain is located on one side of the second semiconductor chip, the second gate and the second source are located on an opposite side of the second semiconductor chip, and the second drain is coupled to the second substrate, and wherein the first semiconductor chip and the second semiconductor chip are located between the first substrate and the second substrate; a first connection structure coupling the first source to the second substrate; and a second connection structure coupling the second source to the first substrate.

Embodiments of the present disclosure relate to a method of manufacturing an electronic device. The method includes: providing a first substrate; disposing a first semiconductor chip on the first substrate; providing a second substrate; disposing a second semiconductor chip on the second substrate; coupling the second substrate to the first semiconductor chip via a first connection structure; and coupling the first substrate to the second semiconductor chip via a second connection structure.

In accordance with one aspect of the present disclosure, an electronic device is provided that includes: a first substrate; a first semiconductor chip on the first substrate, the first semiconductor chip having a first gate, a first source and a first drain, the first drain being coupled to the first substrate and located on a first side of the first semiconductor chip, and the first gate and the first source being located on a second side of the first semiconductor chip opposite to the first side of the first semiconductor chip; a second substrate separated from the first substrate; a second semiconductor chip on the second substrate, the second semiconductor chip having a second gate, a second source and a second drain, the second drain being coupled to the second substrate and located on a first side of the second semiconductor chip, the second gate and the second source being located on a second side of the second semiconductor chip opposite to the first side of the second semiconductor chip, and the first semiconductor chip and the second semiconductor chip being arranged between the first substrate and the second substrate; a first connection structure coupling the first source to the second substrate; and a second connection structure coupling the second source to the first substrate.

In accordance with another aspect of the present disclosure, a method for manufacturing an electronic device is provided that includes: disposing a first semiconductor chip on a first substrate; disposing a second semiconductor chip on a second substrate, the first semiconductor chip and the second semiconductor chip being between the first substrate and the second substrate; coupling the second substrate to the first semiconductor chip via a first connection structure; and coupling the first substrate to the second semiconductor chip via a second connection structure.

In accordance with one aspect of the present disclosure, another electronic device is provided that includes: a first substrate and a second substrate separate from each other; a first semiconductor chip disposed on the first substrate; and a second semiconductor chip disposed on the second substrate, the first semiconductor chip and the second semiconductor chip being between the first substrate and the second substrate; and wherein a drain of the first semiconductor chip is connected to the first substrate using silver sinter bonding, and a source of the first semiconductor chip is connected to the second substrate through a first connection structure using silver sinter bonding; and wherein a drain of the second semiconductor chip is connected to the second substrate using silver sinter bonding, and a source of the second semiconductor chip is connected to the first substrate through a second connection structure using silver sinter bonding.

### BRIEF DESCRIPTION OF THE DRAWINGS

Aspects of embodiments of the present disclosure may be better understood from the following detailed description when read with accompanying drawings. It should be noted that various structures may not be drawn to scale. In fact, the dimensions of the various structures may be enlarged or reduced for discussion clarity.

For a more complete understanding of the present disclosure, and the advantages thereof, reference is now made to the following descriptions taken in conjunction with the accompanying drawings, in which:

FIG. 1A is a top view of an example electronic device according to certain embodiments of the present disclosure;

FIG. 1B is a diagram of an equivalent circuit of the example electronic device according to certain embodiments of the present disclosure;

FIG. 2 is a cross-sectional view of the example electronic device according to certain embodiments of the present disclosure;

FIG. 3 is a perspective view of an example portion of the electronic device according to certain embodiments of the present disclosure;

FIG. 4 is a perspective view of another example portion of the electronic device according to certain embodiments of the present disclosure;

FIG. 5 is an exploded view of the example electronic device according to certain embodiments of the present disclosure;

FIG. 6 is a perspective view of another example portion of the electronic device according to certain embodiments of the present disclosure;

FIG. 7 is a perspective view of another example portion of the electronic device according to certain embodiments of the present disclosure;

FIG. 8 is a schematic diagram showing an example current flow direction of the electronic device according to certain embodiments of the present disclosure;

FIG. 9 is a flowchart of an example method for manufacturing an electronic device according to certain embodiments of the present disclosure; and

FIG. 10 is a flowchart of another example method for manufacturing an electronic device according to certain embodiments of the present disclosure.

Identical or similar components are designated with the same reference numbers in the drawings and detailed description. Embodiments of the present disclosure will be readily understood from the following detailed description taken in conjunction with the accompanying drawings.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

Further, one or more features from one or more of the following described embodiments may be combined to create alternative embodiments not explicitly described, and features suitable for such combinations are understood within the scope of this disclosure. It is therefore intended that the appended claims encompass any such modifications or embodiments.

The following disclosure provides various different embodiments or examples for implementing different features of the presented application. Specific embodiments of components and configurations are described below. Certainly, these are examples only and are not intended to be limiting. In this disclosure, references to forming a first feature over or on a second feature may include embodiments where the first and second features are formed in direct contact, and may also include embodiments where an additional feature is formed between the first feature and the second feature such that the first feature and the second feature may not be in direct contact. In addition, the present disclosure may repeat reference signs and/or letters in various embodiments. Such repetition is for simplicity and clarity and does not in itself indicate a relationship between the various embodiments and/or configurations discussed.

Embodiments of the present disclosure are discussed in detail below. It should be appreciated, however, that the present disclosure provides applicable concepts that can be embodied in a wide variety of specific contexts. The specific embodiments discussed herein are illustrative only, and do not limit the scope of the present disclosure.

The present disclosure provides an electronic device (e.g., an electronic unit, module or component) and a manufacturing method thereof. In the electronic device of the present disclosure, chips are separately arranged on a double-layer substrate to disperse the current, and heat dissipation efficiency of the chips is improved through a heat dissipation structure. In addition, the electronic device of the present disclosure uses a metal layer, instead of wires, as a gate control layer of gates coupled to the chips, which can reduce the circuit wiring area on the printed circuit board. In general, the electronic device of the present disclosure can reduce resistance, disperse heat sources, improve heat dissipation efficiency, and can be miniaturized while satisfying the requirement of higher current and power.

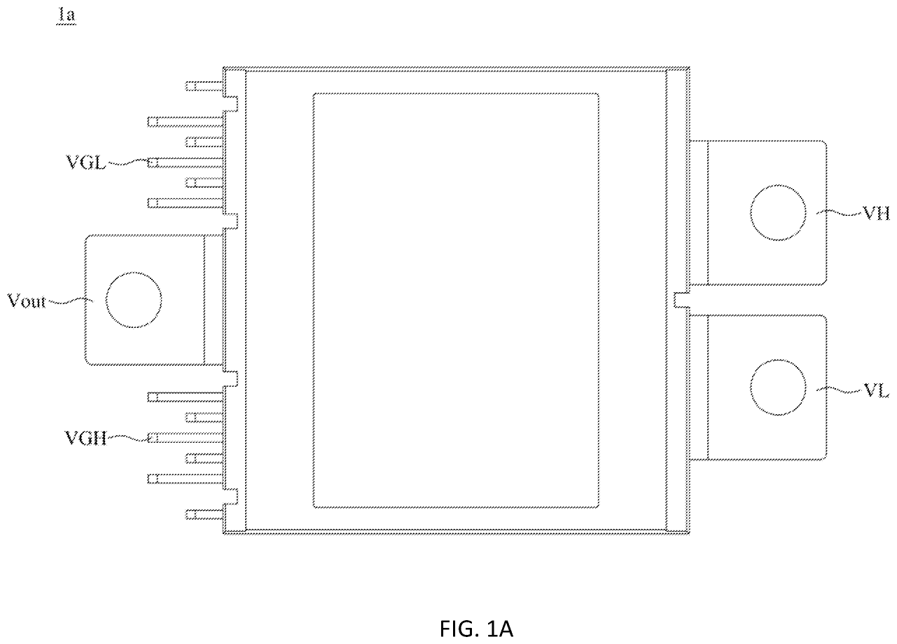

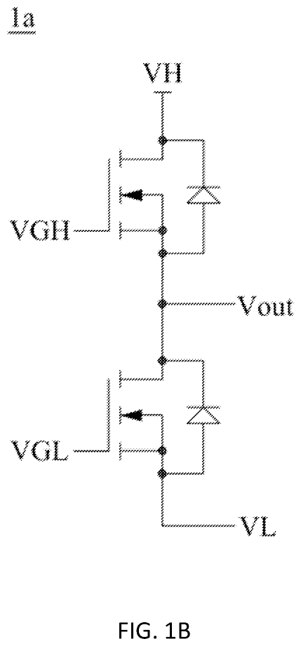

Referring to FIGS. 1A and 1B, FIG. 1A is a top view of an example electronic device 1a according to certain embodiments of the present disclosure, and FIG. 1B is a diagram of an example equivalent circuit of the electronic device 1a according to certain embodiments of the present disclosure. The electronic device 1a may include terminals for connecting to external circuit(s), and the terminals may include (but are not limited to) a first lead VGH, a second lead VGL, an output terminal Vout, a high-voltage terminal VH and a low-voltage terminal VL.

The electronic device 1a may include a semiconductor chip (also referred to as a chip or a die). The semiconductor chip may include circuit components such as transistors, resistors, capacitors, interconnect structures, and so on, to form an integrated circuit (IC). In some embodiments, the electronic device 1a may include a metal-oxide-semiconductor field-effect transistor (MOSFET), such as (but not limited to) a NMOS (negative MOS transistor), PMOS (positive MOS transistor), CMOS (complementary MOS transistor), a voltage feedback device and/or switch. In some embodiments, the electronic device 1a may include a high-voltage transistor, which has a high breakdown voltage (or withstand voltage) and may be applied to circuits with a high input voltage and/or a high output voltage.

The electronic device 1a may include an inverter circuit configured to convert an input direct current (DC) voltage or DC current into an output alternating current (AC) voltage or AC current. However, the present disclosure is not limited thereto. Furthermore, the electronic device 1a may include any type of integrated circuits, such as an amplifier circuit, an oscillator circuit, a rectifier circuit, a filter circuit, a timer circuit, a sensor circuit, a logic circuit, a power supply circuit, a voltage regulator circuit, a communication circuit, and so on.

In some embodiments, as shown in FIG. 1B, an example equivalent circuit of the electronic device 1a may include two NMOSs. The gate of the upper NMOS may be coupled to the first lead VGH, the drain of the upper NMOS may be coupled to the high-voltage terminal VH, and the source of the upper NMOS may be coupled to the output terminal Vout. The gate of the lower NMOS may be coupled to the second lead VGL, the drain of the lower NMOS may be coupled to the output terminal Vout, and the source of the lower NMOS may be coupled to the low-voltage terminal VL. In some embodiments, the two NMOSs may be connected in a cascode configuration.

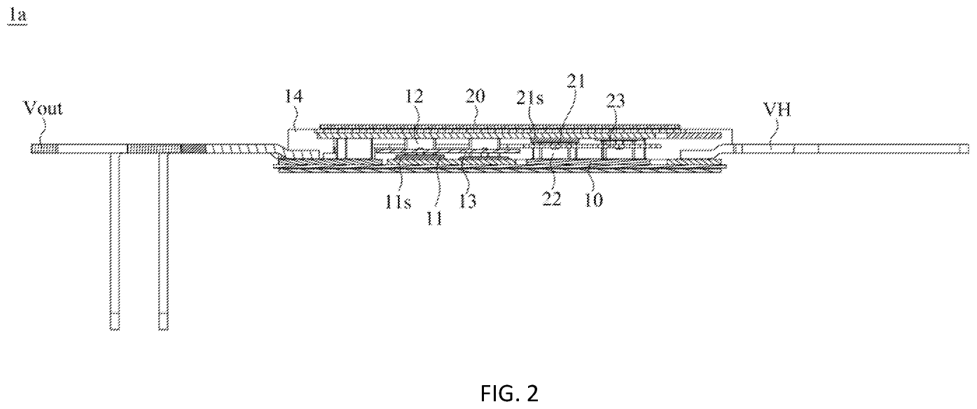

Referring to FIG. 2, FIG. 2 is a cross-sectional view of the electronic device 1a according to certain embodiments of the present disclosure. The electronic device 1a may include a first substrate 10, a second substrate 20, a first semiconductor chip 11, a second semiconductor chip 21, a first connection structure 12, a second connection structure 22, a first gate control layer 13, a second gate control layer 23 and a molding compound layer 14.

The first substrate 10 and the second substrate 20 may each include a ceramic substrate and a circuit (or a heat dissipation structure) formed on one side or both sides of the ceramic substrate. The circuit (or heat dissipation structure) may be bonded to the ceramic substrate via an active metal brazing technique, a diffusion soldering technique, or other methods/techniques. Taking the active metal brazing technique as an example, a bonding layer between the ceramic substrate and the circuit (or heat dissipation structure) may include materials of brazing and active metal. The brazing material may include silver, copper, tin, and so on. The active metal may include titanium, zirconium, and so on. An active metal layer may be formed on the interface between the ceramic and the brazing material. The substrate on which the active metal brazing technique is used may be referred to as an active metal brazing (AMB) substrate. However, the present disclosure is not limited thereto. In some embodiments, the diffusion soldering technique may be used on the first substrate 10 and the second substrate 20, e.g., the substrates may be direct copper bonding (DCB) substrates. The first substrate 10 and the second substrate 20 each may be independent substrates. The first substrate 10 and the second substrate 20 may be physically separated, for example, they may be separated at a distance or they may not be in contact with each other.

One or more chips may be disposed on the first substrate 10 and the second substrate 20, respectively. In some embodiments, one or more chips may be disposed between the first substrate 10 and the second substrate 20. For example, the first semiconductor chip 11 and the second semiconductor chip 21 may be disposed between the first substrate 10 and the second substrate 20. The drain of the first semiconductor chip 11 may be coupled to the first substrate 10, and the drain of the second semiconductor chip 21 may be coupled to the second substrate 20.

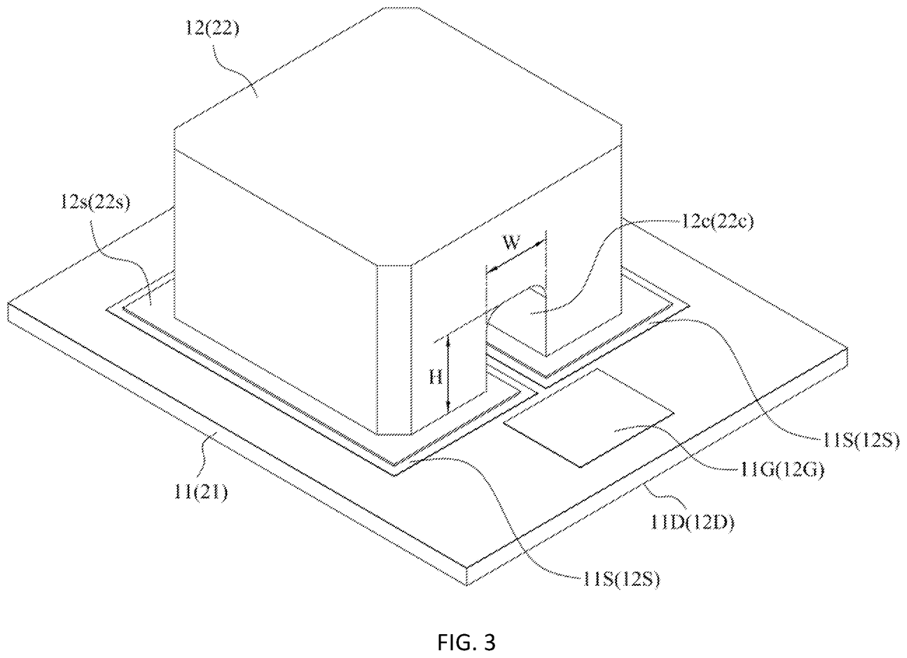

Referring to FIG. 3, FIG. 3 is a perspective view of the first semiconductor chip 11 and the first connection structure 12 according to some embodiments of the present disclosure.

The first semiconductor chip 11 may have one or more electrical terminals, which may be exposed from the surface of the first semiconductor chip 11. For example, the first gate 11G and the first source 11S of the first semiconductor chip 11 may be located on the same side (e.g., a first side) of the first semiconductor chip 11, and the first drain 11D of the first semiconductor chip 11 may be located on the opposite side (e.g., a second side opposite to the first side) of the first semiconductor chip 11. The dimensions (e.g., width, thickness, area, and so on) of the first gate 11G, the first source 11S, and the first drain 11D may be the same as or different from each other. For example, the size of the first drain 11D may be larger than the size of the first source 11S, and the size of the first source 11S may be larger than that of the first gate 11G. The first semiconductor chip 11 may have a plurality of first sources 11S. In the example of FIG. 3, the first semiconductor chip 11 may have two first sources 11S. In other embodiments, the first semiconductor chip 11 may have more than two first sources 11S.

The first drain 11D may be coupled to the first substrate 10 of FIG. 2. In some embodiments, the first drain 11D may be coupled to the first substrate 10 of FIG. 2 using a silver sintering process. For example, in FIG. 2, a silver sintered coating 11s may be disposed between the first drain 11D and the first substrate 10. In some embodiments, the silver sintering process, instead of the wire bonding process, may be used to reduce resistance and improve heat dissipation efficiency. In the example of FIG. 2, the thickness of the silver sintered coating 11s is enlarged in order to show clearly the position of the silver sintered coating 11s. However, the present disclosure is not limited thereto.

The first connection structure 12 may be provided on the first source(s) 11S. The first connection structure 12 may couple the first source(s) 11S to the second substrate 20 in FIG. 2. In some embodiments, the first connection structure 12 may be coupled to the first source(s) 11S using the silver sintering process. For example, a silver sintered coating 12s may be disposed between the first connection structure 12 and the first source(s) 11S. In some embodiments, the first connection structure 12 may be coupled to the second substrate 20 in FIG. 2 through a silver sintering process. For example, a silver sintered coating (not shown) may be disposed between the first connection structure 12 and the second substrate 20 in FIG. 2.

The first connection structure 12 may have a first groove 12c that may span on the two first sources 11S. For example, the first connection structure 12 may have two endpoints separated by the first groove 12, which may be respectively coupled to the two first sources 11S. The first groove 12c may have dimensions, such as a width W and a height H. In some embodiments, the width W and the height H may be greater than (e.g., both greater than) at least three times the dimensions (e.g., maximum width, maximum diameter, average width, average diameter, and so on) of the filler in the molding compound layer 14 in FIG. 2, to facilitate filling of the molding compound layer 14 in FIG. 2 during subsequent process(es). If the width W and height H are too small, the resistance may be too high. In an example, the width W and the height H may range from about 0.100 millimeters (mm) to about 0.300 mm, e.g., from about 0.200 mm to about 0.250 mm. In an example, the width W and the height H may be approximately 0.225 mm.

The second semiconductor chip 21 and the second connection structure 22 may have similar or identical structures as the first semiconductor chip 11 and the first connection structure 12, respectively. For example, referring to the part reference numerals in parentheses in FIG. 3, the second semiconductor chip 21 may have one or more electrical terminals which may be exposed from the surface of the second semiconductor chip 21. For example, the second gate 21G and the second source 21S of the second semiconductor chip 21 may be located on the same side of the second semiconductor chip 21, and the second drain 21D of the second semiconductor chip 21 may be located on the opposite side of the second semiconductor chip 21. The dimensions (e.g., width, thickness, area, and so on) of the second gate 21G, the second source 21S and the second drain 21D may be the same as or different from each other. For example, the second drain 21D may be larger in size than the second source electrode 21S, and the second source 21S may be larger in size than the second gate 21G. The second semiconductor chip 21 may have a plurality of second sources 21S. In the example of FIG. 3, the second semiconductor chip 21 may have two second sources 21S. In other embodiments, the second semiconductor chip 21 may have three or more second sources 21S.

The second drain 21D may be coupled to the second substrate 20 in FIG. 2. In some embodiments, the second drain 21D may be coupled to the second substrate 20 in FIG. 2 using the silver sintering process. For example, in FIG. 2, a silver sintered coating 21s may be disposed between the second drain 21D and the second substrate 20.

The second connection structure 22 may be provided on the second sources 21S. The second connection structure 22 may couple the second sources 21S to the first substrate 10 in FIG. 2. In some embodiments, the second connection structure 22 may be coupled to the second sources 21S using the silver sintering process. For example, a silver sintered coating 22s may be disposed between the second connection structure 22 and the second sources 21S. In some embodiments, the second connection structure 22 may be coupled to the first substrate 10 in FIG. 2 using the silver sintering process. For example, a silver sintered coating (not shown) may be disposed between the second connection structure 22 and the first substrate 10 in FIG. 2.

The second connection structure 22 may have a second groove 22c that may span on the two second sources 21S. For example, the second connection structure 22 may have two endpoints separated by the second groove 22c, which may be respectively coupled to the two second sources 21S. The second groove 22c may have dimensions such as a width W and a height H. In some embodiments, the width W and the height H may be greater than (e.g., both greater than) at least three times the dimensions (e.g., maximum width, maximum diameter, average width, average diameter, and so on) of the filler in the molding compound layer 14 in FIG. 2, to facilitate filling of the molding compound layer 14 in FIG. 2 during subsequent process(es). However, if the width W and height H are too small, the resistance may be too high. For example, the width W and the height H may range from about 0.100 mm to about 0.300 mm, such as from about 0.200 mm to about 0.250 mm. In an example, the width W and the height H may be approximately 0.225 mm.

Referring back to FIG. 2, the drain of the first semiconductor chip 11 (e.g., the first drain 11D in FIG. 3) may be coupled to the first substrate 10, and the drain of the second semiconductor chip 21 (e.g., the second drain 21D in FIG. 3) may be coupled to the second substrate 20. In some embodiments, the drain of the first semiconductor chip 11 may be coupled to the high-voltage terminal VH via the first substrate 10. The drain of the second semiconductor chip 21 may be coupled to a low-voltage terminal (e.g., the low-voltage terminal VL in FIG. 1A) via the second substrate 20. In an embodiment, the operating voltage or current of the first semiconductor chip 11 may be greater than the operating voltage or current of the second semiconductor chip 21. Separately disposing the first semiconductor chip 11 (also referred to as a high-voltage chip) and the second semiconductor chip 21 (also referred to as a low-voltage chip) on different substrates may distribute current, isolate high-voltage and low-voltage circuits, and reduce interference between circuits. In some embodiments, separately arranging the first semiconductor chip 11 and the second semiconductor chip 21 on different substrates may improve heat dissipation capabilities, and avoid thermal interference of high-voltage components with low-voltage components.

The first connection structure 12 may be disposed between the first semiconductor chip 11 and the second substrate 20. The second connection structure 22 may be disposed between the second semiconductor chip 21 and the first substrate 10. In some embodiments, the first connection structure 12 may promote heat dissipation from the first semiconductor chip 11 to the second substrate 20, and the second connection structure 22 may promote heat dissipation from the second semiconductor chip 21 to the first substrate 10. In some embodiments, the first connection structure 12 and the second connection structure 22 may each have electrical conductivity and serve as a part of the circuit of the electronic device 1a. The first connection structure 12 and the second connection structure 22 may each include conductive materials such as metal or metal alloy. Examples of the conductive materials may include gold (Au), silver (Ag), copper (Cu), platinum (Pt), palladium (Pd), other metals or alloys, or a combination of two or more thereof.

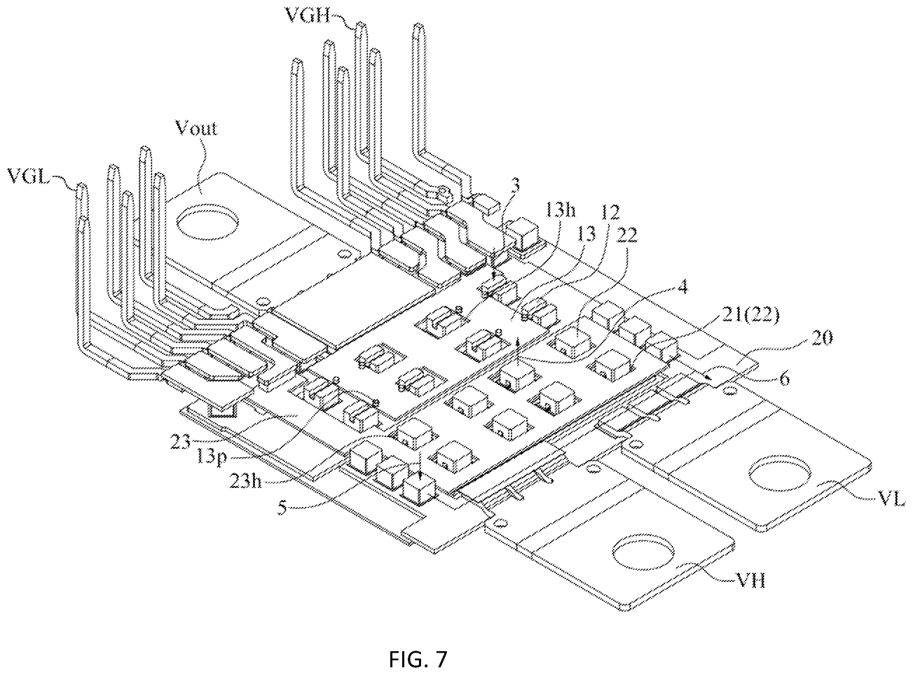

The first gate control layer 13 may be disposed between the first substrate 10 and the second substrate 20, e.g., between the first semiconductor chip 11 and the second substrate 20. The first gate control layer 13 may be coupled to a gate (e.g., the first gate 11G in FIG. 3) through a connector (e.g., a first gate terminal 13p in FIG. 7). The first gate control layer 13 may have an opening 13h as shown in FIG. 7, which is configured to accommodate the first connection structure 12. For example, the first gate control layer 13 may surround the first connection structure 12 but not contact the first connection structure 12. The first gate control layer 13 and the first connection structure 12 may be separated by the molding compound layer 14.

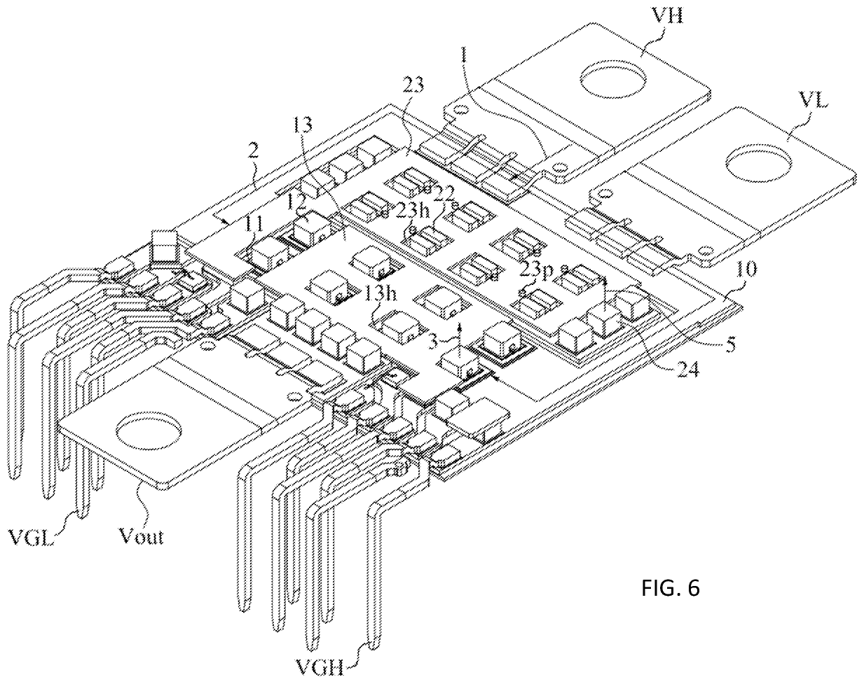

The second gate control layer 23 may be disposed between the first substrate 10 and the second substrate 20, e.g., between the first substrate 10 and the second semiconductor chip 21. The second gate control layer 23 may be coupled to a gate (e.g., the second gate 21G in FIG. 3) through a connector (e.g., a second gate terminal 23p as shown in FIG. 6). The second gate control layer 23 may have an opening 23h as shown in FIG. 6, which is configured to accommodate the second connection structure 22. For example, the second gate control layer 23 may surround the second connection structure 22 but not contact the second connection structure 22. The second gate control layer 23 and the second connection structure 22 may be separated by the molding compound layer 14.

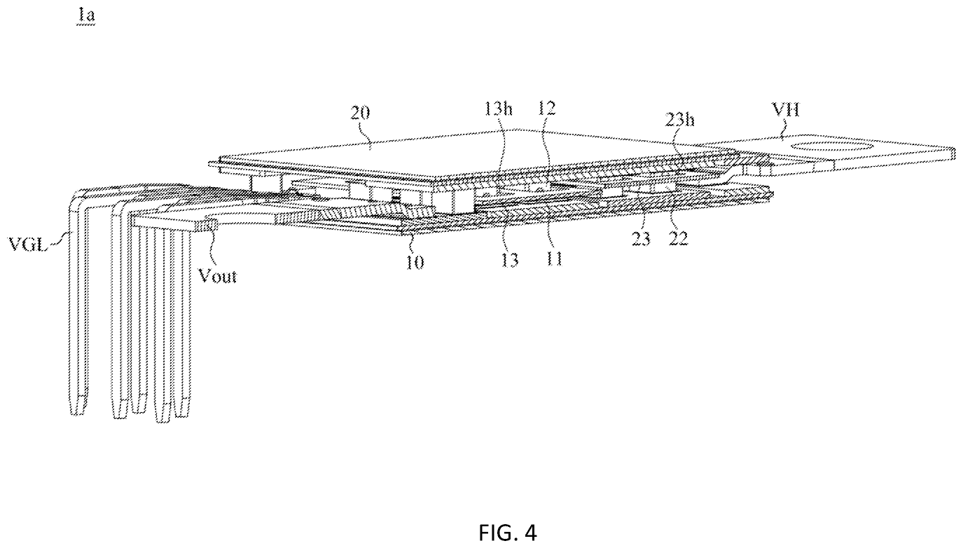

As shown in the cross-sectional view of FIG. 2, the first gate control layer 13 may extend through the first connection structure 12, and the second gate control layer 23 may extend through the second connection structure 22. FIG. 4 is a perspective view of an example portion of the electronic device 1a according to certain embodiments of the present disclosure. As shown in the perspective view of FIG. 4, the first connection structure 12 is located in the opening 13h of the first gate control layer 13 without contacting the first gate control layer 13. The second connection structure 22 is located in the opening 23h of the second gate control layer 23 without contacting the second gate control layer 23. For the sake of simplicity, the molding compound layer 14 is not depicted in FIG. 4.

The first gate control layer 13 and the second gate control layer 23 may be disposed at positions of different heights from the first substrate 10. Using the first gate control layer 13 and the second gate control layer 23 as control layers for controlling the voltages of the first gate 11G and the second gate 21G, compared with using wires for such control, can reduce the circuit wiring area on the printed circuit board. In addition, the first gates 11G of the plurality of first semiconductor chips 11 on the first substrate 10 can be controlled through one first gate control layer 13, which can simplify circuit wiring and improve circuit reliability.

The molding compound layer 14 may be disposed between the first substrate 10 and the second substrate 20, and cover the first semiconductor chip 11, the second semiconductor chip 21, the first connection structure 12, the second connection structure 22, the first gate control layer 13, and second gate control layer 23. The molding compound layer 14 may include a molding compound (for example, an epoxy resin molding compound) or other suitable materials, including (but not limited to) epoxy resins, phenolic resins, silicon-containing resins, or a combination thereof.

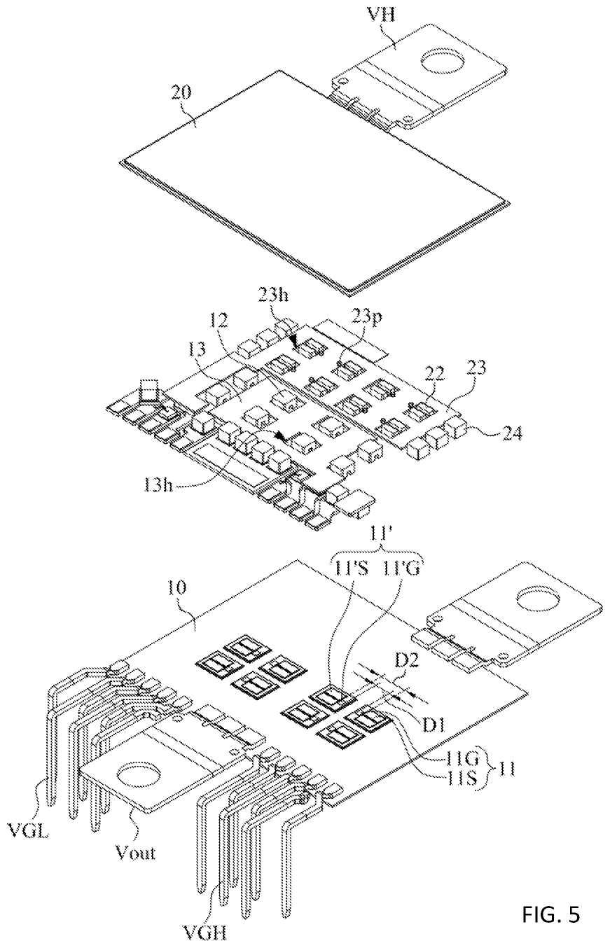

Referring to FIG. 5, FIG. 5 is an example exploded view of the electronic device 1a according to certain embodiments of the present disclosure. A plurality of chips may be disposed on the first substrate 10, such as the first semiconductor chip 11 and a third semiconductor chip 11′. The third semiconductor chip 11′ may have one or more electrical terminals, such as a third gate 11′G, a third source 11'S and a third drain (not shown). The first semiconductor chip 11 and the third semiconductor chip 11′ may be adjacent to each other. A distance D1 between the first gate 11G and the third gate 11′G may be smaller than a distance D2 between the first source 11S and the third source 11'S, which disperses the heat sources and avoids heat accumulation that affects the heat dissipation efficiency. Furthermore, dispersing the heat sources can reduce the junction temperature.

Referring to FIGS. 6 and 7, FIG. 6 is a perspective view of the electronic device 1a with the second substrate 20 removed, and FIG. 7 is a perspective view of the electronic device 1a with the first substrate 10 removed. The first gate control layer 13 may couple the gate of the first semiconductor chip 11 (e.g., the first gate 11G as described with respect to FIG. 3) to the first lead VGH. The high-voltage terminal VH may be coupled to the first lead VGH via the first substrate 10, the first semiconductor chip 11, and the first gate control layer 13. The second gate control layer 23 may couple the gate of the second semiconductor chip 21 (e.g., the second gate 21G as described with respect to FIG. 3) to the second lead VGL. The low-voltage terminal VL may be coupled to the second lead VGL via the second substrate 20, the second semiconductor chip 21, and the second gate control layer 23.

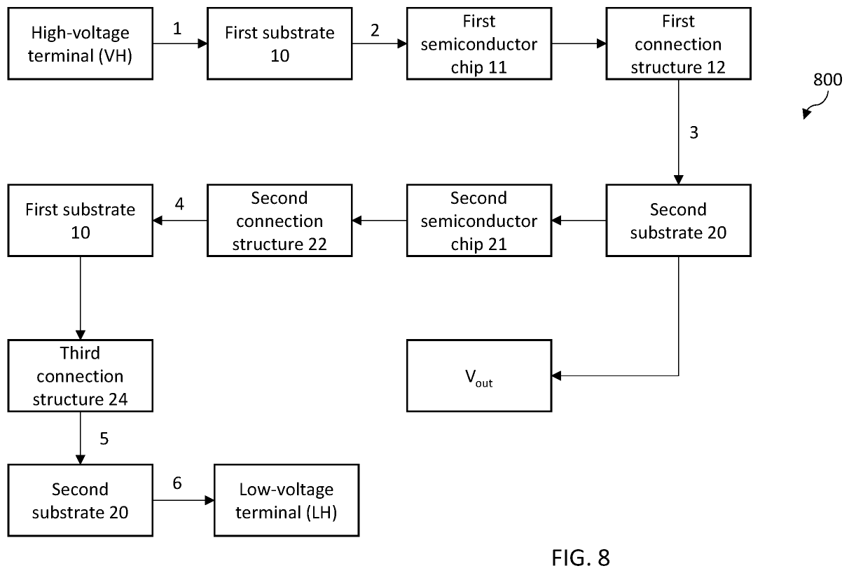

Referring to FIGS. 6, 7 and 8, FIG. 8 is a schematic diagram 800 illustrating example current flow directions of the electronic device 1a according to certain embodiments of the present disclosure.

In some embodiments, the current may flow from the high-voltage terminal VH to the first substrate 10, as indicated by direction 1. The current may flow to the first semiconductor chip 11 through the circuit of the first substrate 10, as indicated by direction 2. In direction 3, the first semiconductor chip 11 and the first connection structure 12 may transfer the current to the second substrate 20. The current may flow to the output terminal Vout through the circuit of the second substrate 20, or be transferred to the second semiconductor chip 21 through the circuit of the second substrate 20. In direction 4, the second semiconductor chip 21 and the second connection structure 22 may transfer the current to the first substrate 10. The circuit of the first substrate 10 may transfer the current to a third connection structure 24 (referring back to FIG. 5 and FIG. 6). As indicated by direction 5, the third connection structure 24 may pass the current to the second substrate 20. As indicated by direction 6, the circuit of the second substrate 20 may deliver the current to the low-voltage terminal VL. The example directions 1-6 are also indicated in FIGS. 6-7.

In some embodiments, the third connection structure 24 may be disposed between the first substrate 10 and the second substrate 20. The third connection structure 24 may be electrically conductive, and may be used to provide electrical connection between the first substrate 10 and the second substrate 20. The third connection structure 24 may be disposed on the periphery or outside of the second gate control layer 23, for example, the third connection structure 24 may not be disposed in the opening 23h of the second gate control layer 23.

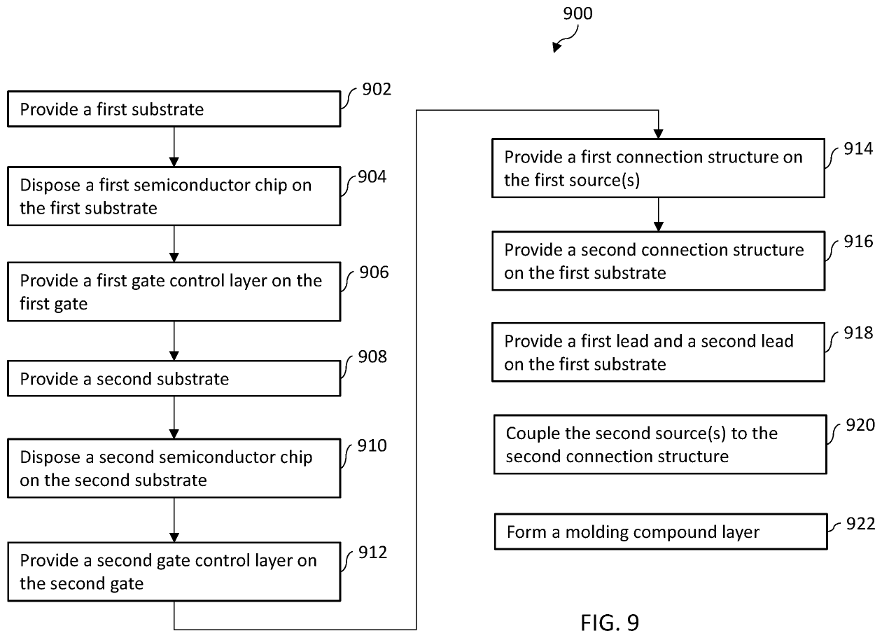

Referring to FIG. 9, FIG. 9 is a flowchart of an example manufacturing method 900 of an electronic device according to certain embodiments of the present disclosure. The manufacturing method 900 includes steps (or stages) 90-100. The steps or stages have been simplified in order for better understanding aspects of the present disclosure. The electronic device formed through these steps may be the same as the electronic device 1a as described with respect to FIG. 2.

As shown, step 902 is to provide a first substrate, such as the first substrate 10 in FIG. 2.

Step 904 is to dispose a first semiconductor chip on the first substrate, such as the first semiconductor chip 11 in FIG. 2. The first semiconductor chip 11 may have the first gate 11G, the first source(s) 11S and the first drain 11D. The first gate 11G and the first source(s) 11S may be located on the same side of the first semiconductor chip 11, and the first drain 11D may be located on an opposite side of the first semiconductor chip 11. In some embodiments, the first semiconductor chip 11 may be coupled to the first substrate, e.g., the first substrate 10 in FIG. 2, through a silver sintering process (also known as a silver sintering bonding technique). In an example, as described with respect to FIG. 2, the silver sintered coating 11s may be disposed between the first drain electrode 11D and the first substrate 10.

Step 906 is to provide a first gate control layer on the first gate, e.g., setting the first gate control layer 13 as described with respect to FIG. 2. The first gate control layer 13 may be coupled to the first gate 11G through the first gate terminal 13p in FIG. 7.

Step 908 is to provide a second substrate, such as the second substrate 20 as described with respect to FIG. 2.

Step 910 is to dispose a second semiconductor chip on the second substrate, e.g., the second semiconductor chip 21 as described with respect to FIG. 2. The second semiconductor chip 21 may have the second gate 21G, the second source(s) 21S and the second drain 21D. The second gate 21G and the second source(s) 21S may be located on a same side of the second semiconductor chip 21, and the second drain 21D may be located on an opposite side of the second semiconductor chip 21. In some embodiments, the second semiconductor chip may be coupled to the second substrate, e.g., the second substrate 20 in FIG. 2, through a silver sintering process or a silver sintering bonding technique. For example, as described with respect to FIG. 2, the silver sintered coating 21s may be disposed between the second drain 21D and the second substrate 20.

Step 912 is to provide a second gate control layer on the second gate, such as the second gate control layer 23 in FIG. 2. The second gate control layer 23 may be coupled to the second gate 21G through the second gate terminal 23p in FIG. 6.

Step 914 is to provide a first connection structure on the first source(s), such as the first connection structure 12 in FIG. 2. For example, the first connection structure 12 may be placed in the opening 13h in FIG. 7.

Step 916 is to provide a second connection structure on the first substrate, such as the second connection structure 22 in FIG. 2.

In some embodiments, the first connection structure and the second connection structure in step 914 and step 916 may be provided in the same step. In some embodiments, the first connection structure and the second connection structure of step 914 and step 916 may be provided before step 908.

Step 918 is to provide a first lead and a second lead on the first substrate, such as the first lead VGH and the second lead VGL in FIG. 1A. In some embodiments, the first lead VGH and the second lead VGL may be bonded to the first substrate 10 through a silver sintering process or ultrasonic bonding technique. In some embodiments, step 918 may also include providing terminals for connecting to other external circuits, such as the output terminal Vout, the high-voltage terminal VH and the low-voltage terminal VL in FIG. 1A. In some embodiments, step 918 may be performed before step 908. In some embodiments, step 918 may be performed before step 904.

Step 920 is to couple the second source(s) to the second connection structure, such as the second connection structure 22 in FIG. 2. For example, the second connection structure 22 may be provided on the first substrate 10 in step 916. The second substrate 20 (and the second semiconductor chip 21 and the second gate control layer 23 thereon) obtained in steps 908, 910 and 912 may be turned over, and combined with the first substrate 10 (and the first semiconductor chip 11, the first gate control layer 13, the first connection structure 12, and the second connection structure 22 thereon) obtained in steps 902, 904, 906, 914 and 916. In this way, the second substrate 20 can be connected to the first semiconductor chip 11 via the first connection structure 12, and the first substrate 10 can be connected to the second semiconductor chip 21 via the second connection structure 22.

Step 922 is to form a molding compound layer, such as the molding compound layer 14 in FIG. 2. In some embodiments, the molding compound layer 14 may be formed by a molding technique such as transfer molding or compression molding.

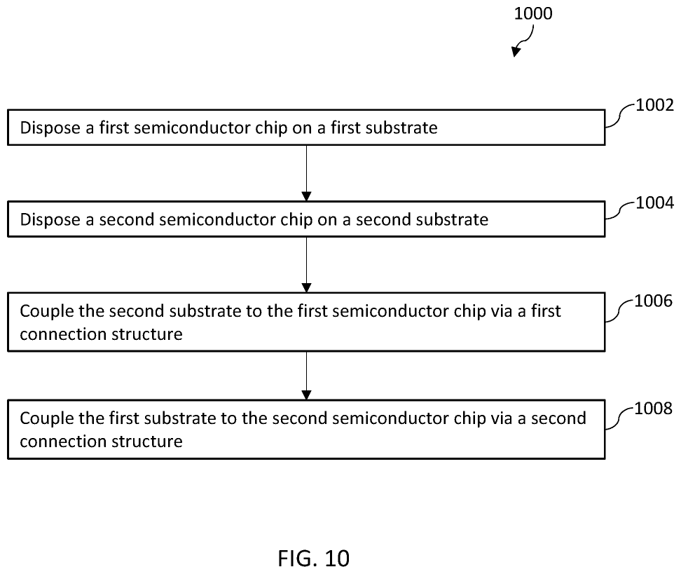

FIG. 10 is a flowchart of another example method 1000 of manufacturing an electronic device according to certain embodiments of the present disclosure. The method 1000 may be used to manufacture the electronic device 1a described above. At step 1002, a first semiconductor chip may be disposed on a first substrate of the electronic device. At step 1004, a second semiconductor chip may be disposed on a second substrate. The first semiconductor chip and the second semiconductor chip are disposed between the first substrate and the second substrate. At step 1006, the second substrate may be coupled to the first semiconductor chip via a first connection structure. At step 1008, the first substrate may be coupled to the second semiconductor chip via a second connection structure. Other steps may further be used in order to manufacture the electronic device 1a as described above.

The following provides further embodiments.

Embodiment 1: An electronic device comprising: a first substrate; a first semiconductor chip having a first gate, a first source and a first drain, wherein the first drain is located on one side of the first semiconductor chip, the first gate and the first source are located on an opposite side of the first semiconductor chip, and the first drain is coupled to the first substrate; a second substrate physically separated from the first substrate; a second semiconductor chip having a second gate, a second source and a second drain, wherein the second drain is located on one side of the second semiconductor chip, the second gate and the second source are located on an opposite side of the second semiconductor chip, and the second drain is coupled to the second substrate, and wherein the first semiconductor chip and the second semiconductor chip are located between the first substrate and the second substrate; a first connection structure coupling the first source to the second substrate; and a second connection structure coupling the second source to the first substrate.

Embodiment 2: The electronic device of Embodiment 1, further comprising: a first gate control layer disposed between the first substrate and the second substrate and coupled to the first gate.

Embodiment 3: The electronic device of Embodiment 2, wherein the first gate control layer has an opening configured to receive the first connection structure.

Embodiment 4: The electronic device of Embodiment 2, wherein the first gate control layer couples the first gate to a first lead.

Embodiment 5: The electronic device of Embodiment 2, further comprising: a second gate control layer disposed between the first substrate and the second substrate and coupled to the second gate.

Embodiment 6: The electronic device of Embodiment 5, wherein the first gate control layer couples the first gate to a first lead, and the second gate control layer couples the second gate to a second lead.

Embodiment 7: The electronic device of Embodiment 6, wherein the first substrate includes a high-voltage terminal of an inverter, the high-voltage terminal coupled to the first lead via the first substrate and the first gate control layer.

Embodiment 8: The electronic device of Embodiment 6, wherein the second substrate includes a low-voltage terminal of an inverter, the low-voltage terminal coupled to the second lead via the second substrate and the second gate control layer.

Embodiment 9: The electronic device of Embodiment 1, further comprising: a molding compound layer disposed between the first substrate and the second substrate, wherein the first connection structure has a groove, and a size of the groove is larger than at least three times a size of a filler in the molding compound layer of at least three times.

Embodiment 10: The electronic device of Embodiment 1, further comprising: a silver sintered coating provided between the first connection structure and the first source.

Embodiment 11: The electronic device of Embodiment 1, further comprising: a silver sintered coating provided between the first drain and the first substrate.

Embodiment 12: The electronic device of Embodiment 1, wherein the first substrate and the second substrate comprise active metal brazing (AMB) substrates.

Embodiment 13: The electronic device of Embodiment 1, further comprising: a third semiconductor chip disposed on the first substrate and having a third gate and a third source, wherein a distance between the third gate and the first gate is smaller than a distance between the third source and the first source.

Embodiment 14: A manufacturing method of an electronic device, comprising: providing a first substrate; disposing a first semiconductor chip on the first substrate; providing a second substrate; disposing a second semiconductor chip on the second substrate; coupling the second substrate to the first semiconductor chip via a first connection structure; and coupling the first substrate to the second semiconductor chip via a second connection structure.

Embodiment 15: The manufacturing method of Embodiment 14, wherein the first semiconductor chip has a first gate, a first source and a first drain, the first drain is located on one side of the first semiconductor chip, and the first gate and the first source are located on an opposite side of the first semiconductor chip, and wherein the first drain is coupled to the first substrate, and the manufacturing method further comprises: providing a first connection structure on the first source.

Embodiment 16: The manufacturing method of Embodiment 14, wherein the second semiconductor chip has a second gate, a second source and a second drain, the second drain electrode is located on one side of the second semiconductor chip, and the second gate and the second source are located on an opposite side of the second semiconductor chip, and wherein the second drain is coupled to the second substrate, and the manufacturing method further includes: providing a second connection structure on the first substrate.

Embodiment 17: The manufacturing method of Embodiment 14, further comprising: disposing a first gate control layer on the first gate, the first gate control layer coupled to the first gate.

Embodiment 18: The manufacturing method of Embodiment 17, further comprising: disposing a second gate control layer on the second gate, the second gate control layer coupled to the second gate.

Embodiment 19: The manufacturing method of Embodiment 14, further comprising: providing a first lead and a second lead on the first substrate.

Embodiment 20: The manufacturing method of Embodiment 14, wherein the first semiconductor chip is bonded to the first substrate by use of silver sinter bonding.

Embodiment 21: The manufacturing method of Embodiment 14, wherein the first connection structure is bonded to the first source by use of silver sinter bonding.

In this disclosure, for description convenience, spatially relative terms such as “below”, “under”, “lower”, “above”, “upper”, “left side”, “right side”, and so on, may be used to describe the relationship of one component or feature with another one or more components or features, as shown in the accompanying drawings. The spatially relative terms are not only used to depict the orientations in the accompanying drawings, but also intended to encompass different orientations of a device in use or operation. A device may be oriented in other ways (rotated 90 degrees or in other orientations), and the spatially relative terms used herein may be interpreted in a corresponding way similarly. It should be understood that when a component is referred to as being “connected” or “coupled” to another component, it can be directly connected or coupled to another component or an intervening component may be present.

As used herein, the terms “approximately”, “basically”, “substantially” and “about” are used to describe and account for small variations. When used in conjunction with an event or instance, the terms may refer to an embodiment of exact occurrence of an event or instance as well as an embodiment where the event or instance is close to the occurrence. As used herein with respect to a given value or range, the term “about” generally means being within +10%, +5%, +1%, or +0.5% of the given value or range. A range herein may be referred to as being from one endpoint to the other or as being between two endpoints. All ranges disclosed herein are inclusive of the endpoints unless otherwise indicated. The term “substantially coplanar” may mean that the difference of positions of two surfaces with reference to the same plane is within a few micrometers (μm), e.g., within 10 μm, within 5 μm, within 1 μm, or within 0.5 μm. When values or characteristics are referred to as being “substantially” the same, the term may refer to a value that is within ±10%, ±5%, ±1%, or ±0.5% of the mean of the values.

The foregoing has outlined features of some embodiments and detailed aspects of present disclosure. The embodiments described in the present disclosure may be readily used as a basis for designing or modifying other processes and structures in order to carry out the same or similar purposes and/or to achieve the same or similar advantages of the embodiments presented herein. Such equivalent constructions do not depart from the spirit and scope of the present disclosure, and various changes, substitutions, and alterations can be made without departing from the spirit and scope of the present disclosure.

The foregoing summary summarizes features of several embodiments and detailed aspects of the disclosure. The embodiments described in this disclosure may readily serve as a basis for designing or modifying other processes and structures for carrying out the same or similar purposes and/or achieving the same or similar advantages of the embodiments introduced herein. Such equivalent constructions do not depart from the spirit and scope of the present disclosure, and various changes, substitutions and alterations may be made without departing from the spirit and scope of the present disclosure

Although the description has been described in detail, it should be understood that various changes, substitutions and alterations can be made without departing from the spirit and scope of this disclosure as defined by the appended claims. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

What is claimed:

1. An electronic device comprising:
a first substrate;
a first semiconductor chip on the first substrate, the first semiconductor chip having a first gate, a first source and a first drain, the first drain being coupled to the first substrate and located on a first side of the first semiconductor chip, and the first gate and the first source being located on a second side of the first semiconductor chip opposite to the first side of the first semiconductor chip;
a second substrate separated from the first substrate;
a second semiconductor chip on the second substrate, the second semiconductor chip having a second gate, a second source and a second drain, the second drain being coupled to the second substrate and located on a first side of the second semiconductor chip, the second gate and the second source being located on a second side of the second semiconductor chip opposite to the first side of the second semiconductor chip, and the first semiconductor chip and the second semiconductor chip being arranged between the first substrate and the second substrate;
a first connection structure coupling the first source to the second substrate; and
a second connection structure coupling the second source to the first substrate.

2. The electronic device of claim 1, further comprising:
a first gate control layer disposed between the first substrate and the second substrate, and coupled to the first gate.

3. The electronic device of claim 2, wherein the first gate control layer has an opening configured to receive the first connection structure.

4. The electronic device of claim 2, wherein the first gate control layer is configured to couple the first gate to a first lead.

5. The electronic device of claim 2, further comprising:
a second gate control layer disposed between the first substrate and the second substrate and coupled to the second gate.

6. The electronic device of claim 5, wherein the first gate control layer is configured to couple the first gate to a first lead, and the second gate control layer is configured to couple the second gate to a second lead.

7. The electronic device of claim 6, wherein the first substrate includes a high-voltage terminal of an inverter, the high-voltage terminal being coupled to the first lead via the first substrate and the first gate control layer.

8. The electronic device of claim 6, wherein the second substrate includes a low-voltage terminal of an inverter, the low-voltage terminal being coupled to the second lead via the second substrate and the second gate control layer.

9. The electronic device of claim 1, further comprising:
a molding compound layer disposed between the first substrate and the second substrate, wherein the first connection structure has a groove, and a size of the groove is larger than at least three times a size of a filler in the molding compound layer.

10. The electronic device of claim 1, further comprising:
a silver sintered coating between the first connection structure and the first source.

11. The electronic device of claim 1, further comprising:
a silver sintered coating between the first drain and the first substrate.

12. The electronic device of claim 1, wherein the first substrate and the second substrate comprise active metal brazing (AMB) substrates.

13. The electronic device of claim 1, further comprising:
a third semiconductor chip disposed on the first substrate, the third semiconductor chip having a third gate and a third source, and a distance between the third gate and the first gate being smaller than a distance between the third source and the first source.

14. A method of manufacturing an electronic device, comprising:
disposing a first semiconductor chip on a first substrate;
disposing a second semiconductor chip on a second substrate, the first semiconductor chip and the second semiconductor chip being disposed between the first substrate and the second substrate;
coupling the second substrate to the first semiconductor chip via a first connection structure; and
coupling the first substrate to the second semiconductor chip via a second connection structure.

15. The method of claim 14, wherein the first semiconductor chip has a first gate, a first source and a first drain, the first drain is coupled to the first substrate and located on a first side of the first semiconductor chip, the first gate and the first source are located on a second side of the first semiconductor chip, the first side being opposite to the second side; and
the method further comprises:
providing the first connection structure on the first source, the first connection structure coupling the first source to the second substrate.

16. The method of claim 15, wherein the first connection structure is bonded to the first source via silver sinter bonding.

17. The method of claim 14, wherein the second semiconductor chip has a second gate, a second source and a second drain, the second drain is coupled to the second substrate and located on a first side of the second semiconductor chip, the second gate and the second source are located on a second side of the second semiconductor chip, the first side being opposite to the second side; and
the method further comprises:
providing the second connection structure on the first substrate, the second connection structure coupling the second source to the first substrate.

18. The method of claim 14, further comprising:
providing a first gate control layer on the first gate, the first gate control layer coupled to the first gate.

19. The method of claim 18, further comprising:
providing a second gate control layer on the second gate, the second gate control layer coupled to the second gate.

20. The method of claim 14, further comprising:
providing a first lead and a second lead on the first substrate.

21. The method of claim 14, wherein the first semiconductor chip is bonded to the first substrate via silver sinter bonding.

22. An electronic device comprising:
a first substrate and a second substrate separate from each other;
a first semiconductor chip disposed on the first substrate; and
a second semiconductor chip disposed on the second substrate, the first semiconductor chip and the second semiconductor chip being between the first substrate and the second substrate; and
wherein a drain of the first semiconductor chip is connected to the first substrate using silver sinter bonding, and a source of the first semiconductor chip is connected to the second substrate through a first connection structure using silver sinter bonding; and
wherein a drain of the second semiconductor chip is connected to the second substrate using silver sinter bonding, and a source of the second semiconductor chip is connected to the first substrate through a second connection structure using silver sinter bonding.

23. The electronic device of claim 22, further comprising:
a first gate control layer coupled to the first gate for controlling a voltage of the first gate, the first gate control layer being disposed between the first semiconductor chip and the second substrate; and
a second gate control layer coupled to the second gate for controlling a voltage of the second gate, the first gate control layer being disposed between the second semiconductor chip and the first substrate.
